(19) United States
(12) Patent Application Publication
(10) Pub. No.: US 2024/0014160 A1
(43) Pub. Date: Jan. 11, 2024

(54) SEMICONDUCTOR PACKAGE

(71) Applicant: Samsung Electronics Co., Ltd., Suwon-si (KR)

(72) Inventors: Seong Ho Shin, Suwon-si (KR); Sang Kyu Kim, Suwon-si (KR); Ju-Youn Choi, Suwon-si (KR)

(21) Appl. No.: 18/348,233

(22) Filed: Jul. 6, 2023

(30) Foreign Application Priority Data
Jul. 11, 2022 (KR) 10-2022-0084782

(51) Int. Cl. H01L 23/00; H01L 21/48; H01L 25/065

(52) U.S. Cl. CPC H01L 24/14; H01L 21/4853; H01L 24/06; H01L 24/73; H01L 25/0657; H01L 2224/73203; H01L 2224/1403; H01L 2924/15311

(57) ABSTRACT

A semiconductor package includes a substrate having opposite first and second surfaces; (1-1)-th substrate pads and (1-2)-th substrate pads on the first surface of the substrate; first connecting terminals on the (1-1)-th substrate pads and the (1-2)-th substrate pads; (2-1)-th substrate pads and (2-2)-th substrate pads on the second surface of the substrate; an interposer on the second surface of the substrate; second connecting terminals between the (2-1)-th substrate pads, the (2-2)-th substrate pads, and the interposer; and a first semiconductor chip on the interposer. The (1-2)-th substrate pads have a smaller maximum width than the (1-1)-th substrate pads. The (2-2)-th substrate pads have a smaller maximum width than the (2-1)-th substrate pads. The (1-1)-th substrate pads and the (2-1)-th substrate pads transmit first signals, ground signals, or power signals. The (1-2)-th substrate pads and the (2-2)-th substrate pads transmit second signals that are faster than the first signals.

### CROSS-REFERENCE TO RELATED APPLICATION

This application claims priority under 35 U.S.C. 119 from Korean Patent Application No. 10-2022-0084782, filed on Jul. 11, 2022 in the Korean Intellectual Property Office, the contents of which are herein incorporated by reference in their entirety.

### TECHNICAL FIELD

Embodiments of the present disclosure are directed to a semiconductor package.

### DISCUSSION OF THE RELATED ART

Due to consumer interest, the demand for high-function, high-speed, and compact-size electronic elements has increased, and high-density and large-scale integration of packages has become important. Ball grid array (BGA) packages have been developed to meet such demand. BGA packages can reduce the mounting area of module substrates and have excellent electrical characteristics, as compared to typical plastic packages.

BGA packages use printed circuit boards (PCBs), whereas typical plastic packages use lead frames. PCBs are useful in terms of the mounting density for module substrates because one surface of each PCB is provided for the mounting of semiconductor chips and the other surface of each PCB is provided for the formation of solder balls, which are external connecting terminals.

### SUMMARY

Embodiments of the present disclosure provide a semiconductor package with an improved product reliability.

According to an embodiment of the present disclosure, there is provided a semiconductor package that includes a package substrate that includes first and second surfaces that are opposite to each other; (1-1)-th substrate pads and (1-2)-th substrate pads disposed on the first surface of the package substrate, where the (1-2)-th substrate pads have a smaller maximum width than the (1-1)-th substrate pads; first connecting terminals disposed on the (1-1)-th substrate pads and the (1-2)-th substrate pads; (2-1)-th substrate pads and (2-2)-th substrate pads disposed on the second surface of the package substrate, where the (2-2)-th substrate pads have a smaller maximum width than the (2-1)-th substrate pads; an interposer disposed on the second surface of the package substrate; second connecting terminals disposed between the (2-1)-th substrate pads, the (2-2)-th substrate pads, and the interposer; and a first semiconductor chip disposed on the interposer. The (1-1)-th substrate pads and the (2-1)-th substrate pads transmit first signals, ground signals, or power signals, and the (1-2)-th substrate pads and the (2-2)-th substrate pads transmit second signals that are faster than the first signals.

According to another embodiment of the present disclosure, there is provided a semiconductor package that includes a package substrate that includes first and second surfaces that are opposite to each other; first connecting terminals disposed on the first surface of the package substrate; an interposer disposed on the second surface of the package substrate, wherein the interposer includes a third surface that faces the second surface and a fourth surface that is opposite to the third surface; (1-1)-th connecting pads and (1-2)-th connecting pads disposed on the third surface of the interposer, where the (1-2)-th connecting pads have a smaller maximum width than the (1-1)-th connecting pads; second connecting terminals disposed between the (1-1)-th connecting pads, the (1-2)-th connecting pads, and the package substrate; (2-1)-th connecting pads and (2-2)-th connecting pads disposed on the fourth surface of the interposer, where the (2-1)-th connecting pads and the (2-2)-th connecting pads have a same maximum width; a semiconductor chip disposed on the fourth surface of the interposer; and third connecting terminals disposed between the (2-1)-th connecting pads, the (2-2)-th connecting pads, and the semiconductor chip. The (1-1)-th connecting pads and the (2-1)-th connecting pads transmit first signals, ground signals, or power signals, and the (1-2)-th connecting pads and the (2-2)-th connecting pads transmit second signals that are faster than the first signals.

According to another embodiment of the present disclosure, there is provided a semiconductor package that includes a package substrate that includes first and second surfaces that are opposite to each other; (1-1)-th substrate pads and (1-2)-th substrate pads disposed on the first surface of the package substrate, where the (1-2)-th substrate pads have a smaller maximum width than the (1-1)-th substrate pads; first connecting terminals disposed on the (1-1)-th substrate pads and the (1-2)-th substrate pads; (2-1)-th substrate pads and (2-2)-th substrate pads disposed on the second surface of the package substrate, where the (2-2)-th substrate pads have a smaller maximum width than the (2-1)-th substrate pads; an interposer disposed on the second surface of the package substrate, where the interposer includes a third surface that faces the second surface and a fourth surface that is opposite to the third surface; (1-1)-th connecting pads and (1-2)-th connecting pads disposed on the third surface of the interposer, where the (1-2)-th connecting pads have a smaller maximum width than the (1-1)-th connecting pads; second connecting terminals disposed between the (2-1)-th substrate pads and the (1-1)-th connecting pads and between the (2-2)-th substrate pads and the (1-2)-th connecting pads; (2-1)-th connecting pads and (2-2)-th connecting pads disposed on the fourth surface of the interposer, where the (2-1)-th connecting pads and the (2-2)-th connecting pads have a same maximum width; a semiconductor chip disposed on the fourth surface of the interposer; first chip pads and second chip pads disposed on a fifth surface of the semiconductor chip that faces the fourth surface of the interposer, where the first chip pads and the second chip pads have a same width; and third connecting terminals disposed between the (2-1)-th connecting pads and the first chip pads and between the (2-2)-th connecting pads and the second chip pads. The (1-1)-th substrate pads, the (2-1)-th substrate pads, the (1-1)-th connecting pads, the (2-1)-th connecting pads, and the first chip pads transmit first signals, ground signals, or power signals, and the (1-2)-th substrate pads, the (2-2)-th substrate pads, the (1-2)-th connecting pads, the (2-2)-th connecting pads, and the second chip pads transmit second signals that have a different speed from the first signals.

### BRIEF DESCRIPTION OF THE DRAWINGS

FIG. 1 illustrates a semiconductor package according to some embodiments of the present disclosure.

FIG. 2 illustrates first substrate pads of FIG. 1.

FIG. 3 illustrates second substrate pads of FIG. 1.

FIG. 4 illustrates first connecting pads of FIG. 1.

FIG. 5 illustrates second connecting pads of FIG. 1.

FIG. 6 is a graph showing the loss of high-speed signals for differing sizes of (1-2)-th and (2-1)-th connecting pads of FIG. 1.

FIGS. 7 through 13 illustrate semiconductor packages according to some embodiments of the present disclosure.

### DETAILED DESCRIPTION

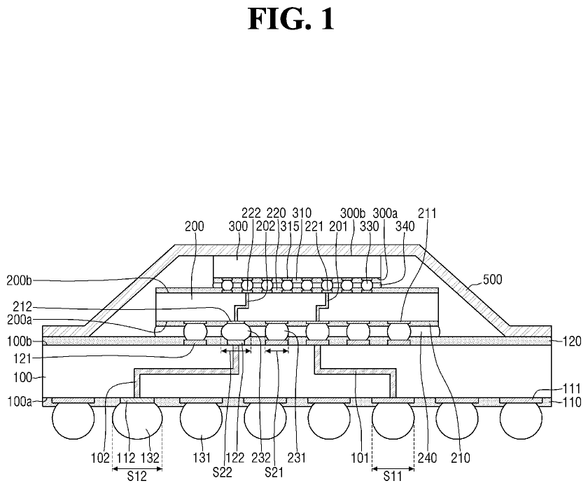

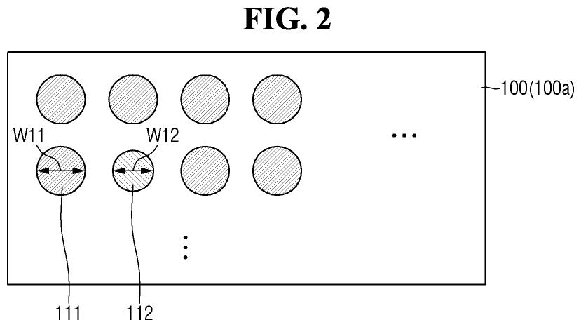

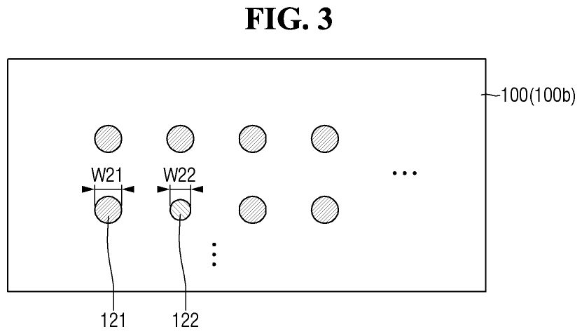

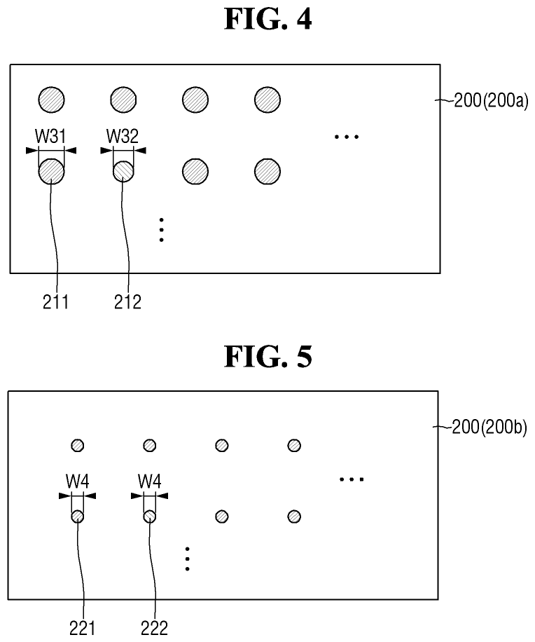

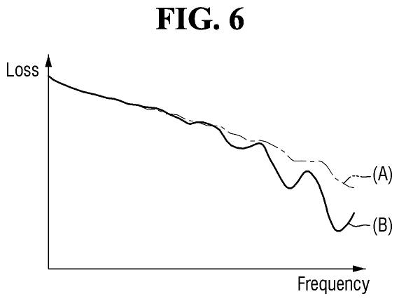

FIG. 1 illustrates a semiconductor package according to some embodiments of the present disclosure. FIG. 2 illustrates first substrate pads of FIG. 1. FIG. 3 illustrates second substrate pads of FIG. 1. FIG. 4 illustrates first connecting pads of FIG. 1. FIG. 5 illustrates second connecting pads of FIG. 1. FIG. 6 is a graph showing the loss of high-speed signals versus the size of (1-2)-th and (2-1)-th connecting pads of FIG. 1.

Referring to FIGS. 1 through 5, in some embodiments, a semiconductor package may include a package substrate 100, first substrate pads 111 and 112, first solder resist 110, second substrate pads 121 and 122, second solder resist 120, first wiring patterns 101 and 102, first connecting terminals 131 and 132, a first interposer 200, first connecting pads 211 and 212, a first passivation layer 210, second connecting pads 221 and 222, a second passivation layer 220, second wiring patterns 201 and 202, second connecting terminals 231 and 232, a first underfill material layer 240, a first semiconductor chip 300, first chip pads 315, a third passivation layer 310, third connecting terminals 330, a second underfill material layer 340, and a heat dissipation structure 500.

The package substrate 100 has first and second surfaces 100a and 100b, that are opposite to each other. The package substrate 100 may be, for example, a printed circuit board (PCB). When the package substrate 100 is a PCB, the package substrate 100 is formed of at least one of a phenolic resin, an epoxy resin, or polyimide. For example, the package substrate 100 includes at least one of FR4, tetrafunctional epoxy, polyphenylene ether, epoxy/polyphenylene oxide, bismaleimide triazine (BT), Thermount, cyanate ester, polyimide, or a liquid crystal polymer.

The first substrate pads 111 and 112 are disposed on the first surface 100a of the package substrate 100. The first solder resist 110 is disposed on the first surface 100a of the package substrate 100. The first substrate pads 111 and 112 are disposed in the first solder resist 110. The first solder resist 110 exposes at least parts of the first substrate pads 111 and 112.

The second substrate pads 121 and 122 are disposed on the second surface 100b of the package substrate 100. The second solder resist 120 is disposed on the second surface 100b of the package substrate 100. The second substrate pads 121 and 122 are disposed in the second solder resist 120. The second solder resist 120 exposes at least parts of the first substrate pads 121 and 122. The first substrate pads 111 and 112 and the second substrate pads 121 and 122 include a metal such as copper (Cu) or aluminum (Al), but embodiments of the present disclosure are not necessarily limited thereto.

The first wiring patterns 101 and 102 are disposed in the package substrate 100. The first wiring patterns 101 and 102 include a plurality of wirings and vias that are spaced apart from each other in a direction normal to the first surface 100a of the package substrate 100 or a direction parallel to the first surface 100a. The first wiring patterns 101 and 102 include a metal such as Cu or Al, but embodiments of the present disclosure are not necessarily limited thereto. The number of first wiring patterns 101 and 102 and the distance between and the layout of the first wiring patterns 101 and 102 are not particularly limited.

The first wiring patterns 101 and 102 perform various functions, depending on how they are designed. For example, in an embodiment, the first wiring patterns 101 and 102 include ground (GND) patterns, power (PWR) patterns, and signal (S) patterns. The signal patterns transmit various signals, except for ground signals and power signals, such as data signals. The first substrate pads 111 and 112 and the second substrate pads 121 and 122 are connected to the first wiring patterns 101 and 102 and thus transmit the ground signals, the power signals, and other signals.

In some embodiments, (1-1)-th wiring patterns 101 include first signal patterns, and (1-2)-th wiring patterns 102 include second signal patterns. Second signals, which are transmitted via the second signal patterns are faster than first signals, which are transmitted via the first signal patterns. For example, the second signals are high-speed signals, and the first signals are regular signals that are slower than the second signals. (1-1)-th substrate pads 111 and (2-1)-th substrate pads 121 are connected to the (1-1)-th wiring patterns 101 and transmit the ground signals, the power signals, or the first signals, and (1-2)-th substrate pads 112 and (2-2)-th substrate pads 122 are connected to the (1-2)-th wiring patterns 102 and may transmit the second signals. The numbers of first substrate pads 111 and 112 and second substrate pads 121 and 122, the distances between the first substrate pads 111 and 112 and between the second substrate pads 121 and 122, and the layouts of the first substrate pads 111 and 112 and the second substrate pads 121 and 122 are not particularly limited.

In some embodiments, a maximum width W11 of the (1-1)-th substrate pads 111 differs from a maximum width W12 of the (1-2)-th substrate pads 112. The maximum width W12 of the (1-2)-th substrate pads 112, which transmit the second signals, is less than the maximum width W11 of the (1-1)-th substrate pads 111, which do not transmit the second signals. For example, the maximum width W11 of the (1-1)-th substrate pads 111 is the diameter of the (1-1)-th substrate pads 111, and the maximum width W12 of the (1-2)-th substrate pads 112 may be the diameter of the (1-2)-th substrate pads 112.

The first connecting terminals 131 and 132 are disposed on the first substrate pads (111 and 112). (1-1)-th connecting terminals 131 are disposed on and electrically connected to the (1-1)-th substrate pads 111, and (1-2)-th connecting terminals 132 are disposed on and electrically connected to the (1-2)-th substrate pads 112. The (1-1)-th connecting terminals 131 transmit the ground signals, the power signals, or the first signals, and the (1-2)-th connecting terminals 132 transmit the second signals.

The bottom surfaces of the (1-1)-th connecting terminals 131 are substantially coplanar with the bottom surfaces of the (1-2)-th connecting terminals 132. For example, the maximum height from the first surface 100a of the package substrate 100 to the bottom surface of the (1-1)-th connecting terminals 131 is substantially the same as the maximum height from the first surface 100a of the package substrate 100 to the bottom surface of the (1-2)-th connecting terminals 132.

In some embodiments, a maximum width S11 of the (1-1)-th connecting terminals 131 differs from a maximum width S12 of the (1-2)-th connecting terminals 132. The maximum width S12 of the (1-2)-th connecting terminals 132, which transmit the second signals, is greater than the maximum width S11 of the (1-1)-th connecting terminals 131, which do not transmit the second signals. For example, substantially the same number of pre-connecting terminals are formed on the (1-1)-th substrate pads 111 and on the (1-2)-th substrate pads 112, but as the maximum width W11 of the (1-1)-th substrate pads 111 differs from the maximum width W12 of the (1-2)-th substrate pads 112, the maximum width S11 of the (1-1)-th connecting terminals 131 differs from the maximum width S12 of the (1-2)-th connecting terminals 132.

The first interposer 200 is disposed on the package substrate 100. The first interposer 200 is disposed on the second surface 100b of the package substrate 100. The first interposer 200 has third and fourth surfaces 200a and 200b that are opposite to each other. The third surface 200a of the first interposer 200 faces the second surface 200b of the package substrate 100. The first interposer 200 may be, for example, a silicon interposer. Alternatively, in some embodiments, the first interposer 200 includes at least one of, for example, glass, ceramic, or plastic.

The first connecting pads 211 and 212 are disposed on the third surface 200a of the first interposer 200. The first passivation layer 210 is disposed on the third surface 200a of the first interposer 200. The first passivation layer 210 exposes at least parts of the first connecting pads 211 and 212.

The second connecting pads 221 and 222 are disposed on the fourth surface 200b of the first interposer 200. The second passivation layer 220 is disposed on the fourth surface 200b of the first interposer 200. The second passivation layer 220 exposes at least parts of the second connecting pads 221 and 222. The first connecting pads 211 and 212 and the second connecting pads 221 and 222 include a metal, such as Cu or Al

The second wiring patterns 201 and 202 are disposed in the first interposer 200. The second wiring patterns 201 and 202 include a plurality of wirings and vias that are spaced apart from each other in a direction normal to the third surface 200a of the first interposer 200 or a direction in parallel to the third surface 200a. The second wiring patterns 201 and 202 include a metal, such as Cu or Al, but embodiments of the present disclosure are not necessarily limited thereto. The number of second wiring patterns 201 and 202, and the distance between and the layout of the second wiring patterns 201 and 202 are not particularly limited.

In some embodiments, (2-1)-th wiring patterns 201 are electrically connected to the (1-1)-th wiring patterns 101, and (2-2)-th wiring patterns 202 are electrically connected to the (1-2)-th wiring patterns 102. The (2-1)-th wiring patterns 201 include ground patterns, power patterns, and first signal patterns, and the (2-2)-th wiring patterns 202 include second signal patterns. (1-1)-th connecting pads 211 and (2-1)-th connecting pads 221 are connected to the (2-1)-th wiring patterns 201 and transmit the ground signals, the power signals, or the first signals, and (1-2)-th connecting pads 212 and (2-2)-th connecting pads 222 are connected to the (2-2)-th wiring patterns 202 and transmit the second signals. The number of first connecting pads 211 and 212 and second connecting pads 221 and 222, the distances between the first connecting pads 211 and 212 and between the second connecting pads 221 and 222, and the layouts of the first connecting pads 211 and 212 and the second connecting pads 221 and 222 are not particularly limited.

In some embodiments, a maximum width W31 of the (1-1)-th connecting pads 211 differs from a maximum width W32 of the (1-2)-th connecting pads 212. The maximum width W32 of the (1-2)-th connecting pads 212, which transmit the second signals, is less than the maximum width W31 of the (1-1)-th connecting pads 211, which do not transmit the second signals. For example, the maximum width W31 of the (1-1)-th connecting pads 211 is the diameter of the (1-1)-th connecting pads 211, and the maximum width W32 of the (1-2)-th connecting pads 212 is the diameter of the (1-2)-th connecting pads 212.

In some embodiments, the (2-1)-th connecting pads 221 and the (2-2)-th connecting pads 222 have substantially the same maximum width, such as a width W4. For example, the width W4 is the diameter of the (2-1)-th connecting pads 221 and the diameter of the (2-2)-th connecting pads 222.

The second connecting terminals 231 and 232 are disposed between the package substrate 100 and the first interposer 200. The second connecting terminals 231 and 232 are disposed between the second substrate pads 121 and 122 and the first connecting pads 211 and 212. (2-1)-th connecting terminals 231 are disposed between and electrically connected to the (2-1)-th substrate pads 121 and the (1-1)-th connecting pads 211, and (2-2)-th connecting terminals 232 are disposed between and electrically connected to the (2-2)-th substrate pads 122 and the (1-2)-th connecting pads 212. The (2-1)-th connecting terminals 231 transmit the ground signals, the power signals, or the first signals, and the (2-2)-th connecting terminals 232 transmit the second signals.

In some embodiments, a maximum width S21 of the (2-1)-th connecting terminals 231 differs from a maximum width S22 of the (2-2)-th connecting terminals 232. The maximum width S22 of the (2-2)-th connecting terminals 232, which transmit the second signals, is greater than the maximum width S21 of the (2-1)-th connecting terminals 231, which do not transmit the second signals, and this originates from how the second connecting terminals 231 and 232 are fabricated. For example, substantially the same number of pre-connecting terminals are formed on the first substrate pads 121 and 122 or on the first connecting pads 211 and 212, but as the maximum width W21 of the (2-1)-th substrate pads 121 differs from the maximum width W22 of the (2-2)-th substrate pads 122 and the maximum width W31 of the (1-1)-th connecting pads 211 differs from the maximum width W32 of the (1-2)-th connecting pads 212, the maximum width S21 of the (2-1)-th connecting terminals 231 differs from the maximum width S22 of the (2-2)-th connecting terminals 232.

The first underfill material layer 240 is disposed between the package substrate 100 and the first interposer 200. The first underfill material layer 240 fills the gap between the package substrate 100 and the first interposer 200. The first underfill material layer 240 fills the gaps between the second connecting terminals 231 and 232 and surrounds the second connecting terminals 231 and 232. Alternatively, in an embodiment, the first underfill material layer 240 extends upward along the sides of the first passivation layer 210 and the sides of the first interposer 200. The first underfill material layer 240 protects the second connecting terminals 231 and 232.

The first semiconductor chip 300 is disposed on the first interposer 200. The first semiconductor chip 300 is disposed on the fourth surface 200b of the first interposer 200. The first semiconductor chip 300 has fifth and sixth surfaces 300a and 300b that are opposite to each other. The fifth surface 300a of the first semiconductor chip 300 faces the fourth surface 200b of the first interposer 200.

The first semiconductor chip 300 may be a semiconductor logic chip or a semiconductor memory chip. The semiconductor logic chip may be an application processor (AP) such as a central processing unit (CPU), a graphic processing unit (GPU), a field-programmable gate array (FPGA), a digital signal processor, a cryptographic processor, a microprocessor, a microcontroller, or an application-specific integrated circuit (ASIC), but embodiments of the present disclosure are not necessarily limited thereto. The semiconductor memory chip may be, for example, a volatile memory such as a dynamic random-access memory (DRAM) or a static random-access memory (SRAM), or a nonvolatile memory such as a flash memory, a phase-change random-access memory (PRAM), a magnetic random-access memory (MRAM), a ferroelectric random-access memory (FeRAM), or a resistive random-access memory (RRAM).

The first chip pads 315 are disposed on the fifth surface 300a of the first semiconductor chip 300. The first chip pads 315 include a metal, such as Cu or Al, but embodiments of the present disclosure are not necessarily limited thereto. The number of first chip pads 315 and the distance between and the layout of the first chip pads 315 are not particularly limited.

The third passivation layer 310 is disposed on the fifth surface 300a of the first semiconductor chip 300. The third passivation layer 310 exposes at least parts of the first chip pads 315. The first, second, and third passivation layers 210, 220, and 310 each include silicon nitride. Alternatively, in an embodiment, the first, second, and third passivation layers 210, 220, and 310 include a passivation material, such as benzocyclobutene (BCB), polybenzoxazole, polyimide, epoxy, silicon oxide, silicon nitride, or a combination thereof.

The third connecting terminals 330 are disposed between the first interposer 200 and the first semiconductor chip 300. The third connecting terminals 330 are disposed between the second connecting pads 221 and 222 and the first chip pads 315. The third connecting terminals 330 are disposed on and electrically connected to the second connecting pads 221 and 222 and the first chip pads 315. The third connecting terminals 330 are electrically connected to the (2-1)-th connecting pads 221 to transmit the ground signals, the power signals, or the first signals, and are electrically connected to the (2-2)-th connecting pads 222 to transmit the second signals. Accordingly, the first chip pads 315 transmit the ground signals, the power signals, or the first signals, or transmit the second signals.

In some embodiments, the first chip pads 315 each have substantially the same maximum width. The maximum width of the first chip pads 315 is the diameter of the first chip pads 315. For example, first chip pads 315 that transmit the ground signals, the power signals, and the first signals have substantially the same maximum width as first chip pads 315 that transmit the second signals. The third connecting terminals 330 each have substantially the same maximum width. For example, third connecting terminals 330 that transmit the ground signals, the power signals, and the first signals, have substantially the same maximum width as third connecting terminals 330 that transmit the second signals.

The first connecting terminals 130, the second connecting terminals 230, and the third connecting terminals 230 may be, for example, solder bumps, but embodiments of the present disclosure are not necessarily limited thereto. The first connecting terminals 130, the second connecting terminals 230, and the third connecting terminals 230 may have various shapes, such as a ball, pin, or pillar shape. The number of first connecting terminals 130, second connecting terminals 230, and third connecting terminals 230, the distances between the first connecting terminals 130, between the second connecting terminals 230, and between the third connecting terminals 230, and the layouts of the first connecting terminals 130, the second connecting terminals 230, and the third connecting terminals 230, are not particularly limited, and may vary. The first connecting terminals 130, the second connecting terminals 230, and the third connecting terminals 230 may have different sizes. For example, the first connecting terminals 130 are larger than the second connecting terminals 230, and the second connecting terminals 230 are larger than the third connecting terminals 330.

The first connecting terminals 130, the second connecting terminals 230, and the third connecting terminals 230 include, for example, at least one of tin (Sn), indium (In), bismuth (Bi), antimony (Sb), Cu, silver (Ag), zinc (Zn), lead (Pb), or a combination thereof, but embodiments of the present disclosure are not necessarily limited thereto.

The second underfill material layer 340 is disposed between the first interposer 200 and the first semiconductor chip 300. The second underfill material layer 340 fills the gap between the first interposer 200 and the first semiconductor chip 300. The second underfill material layer 340 fills the gaps between the third connecting terminals 330 and may surround the third connecting terminals 330. Alternatively, in an embodiment, the second underfill material layer 340 extends upward along the sides of the third passivation layer 310 and the sides of the first semiconductor chip 300. The second underfill material layer 340 protects the third connecting terminals 330. The first and second underfill material layers 240 and 340 include an insulating polymer material, such as an epoxy molding compound (EMC), but embodiments of the present disclosure are not necessarily limited thereto.

In some embodiments, the heat dissipation structure 500 is disposed on the second surface 100b of the package substrate 100 and covers the first interposer 200 and the first semiconductor chip 300. The heat dissipation structure 500 is attached to, for example, the sixth surface 300b of the first semiconductor chip 300. The heat dissipation structure 500 may have various shapes other than that illustrated in FIG. 1. The heat dissipation structure 500 includes a conductive material, such as a metal or a metal alloy that includes at least one of gold (Au), Ag, Cu, or iron (Fe), graphite, or graphene. The heat dissipation structure 500 is attached to the package substrate 100 by, for example, an adhesive. For example, the adhesive is one of a thermally conductive adhesive tape, a thermally conductive grease, or a thermally conductive adhesive.

The first solder resist 110 covers at least parts of the first substrate pads 111 and 112.

Impedance discontinuities can occur due to the capacitances caused by the first connecting terminals 131 and 132, the first substrate pads 111 and 112, and parts of the first solder resistance 110 between the first substrate pads 111 and 112 and the first connecting terminals 131 and 132. When passing through regions with impedance discontinuities, some high-speed signals may be reflected and thereby distorted, and as a result the quality of the high speed signal is degraded. Impedance discontinuities can also occur in the second substrate pads 121 and 122, the first connecting pads 211 and 212, the second connecting pads 221 and 222, and the first chip pads 315.

However, in a semiconductor package of FIGS. 1 through 5, the maximum widths of the (1-2)-th substrate pads 112, the (2-2)-th substrate pads 122, and the (1-2)-th connecting pads 212 that transmit high-speed signals is less than the maximum widths of the (1-1)-th substrate pads 111, the (2-1)-th substrate pads 121, and the (1-1)-th connecting pads 211 that do not transmit high-speed signals. Accordingly, the capacitances formed in the (1-2)-th substrate pads 112, the (2-2)-th substrate pads 122, and the (1-2)-th connecting pads 212 can be reduced, and as a result, regions with impedance discontinuities can also be reduced.

The (2-2)-th connecting pads 222 and the first chip pads 315 are smaller than the (1-2)-th substrate pads 112, the (2-2)-th substrate pads 122, and the (1-2)-th connecting pads 212. Thus, the capacitances formed in the (2-2)-th connecting pads 222 and the first chip pads 315 are negligible as compared to the capacitances formed in the (1-2)-th substrate pads 112, the (2-2)-th substrate pads 122, and the (1-2)-th connecting pads 212. Accordingly, even though the maximum widths of the (2-2)-th connecting pads 222 and first chip pads 315, which do not transmit high-speed signals, are substantially the equal to the maximum widths of the (2-1)-th connecting pads 221 and first chip pads 315, which transmit the high-speed signals, the quality of the high-speed signals is increased because the capacitances formed in the (1-2)-th substrate pads 112, the (2-2)-th substrate pads 122, and the (1-2)-th connecting pads 212 are reduced.

For example, if the maximum width of the (1-2)-th substrate pads 112 is 380 μm, a capacitance of 80 fF forms in the (1-2)-th substrate pads 112, and if the maximum width of the (1-2)-th connecting pads 212 is 200 μm, a capacitance of 50 fF forms in the (1-2)-th connecting pads 212. When the maximum widths of the (1-2)-th substrate pads 112 and the (1-2)-th connecting pads 212 are reduced by about 15%, the capacitances formed in the (1-2)-th substrate pads 112 and the (1-2)-th connecting pads 212 are reduced by about 30%.

Referring to FIG. 6, curve (A) represents the loss of high-speed signals as a function of frequency when the first substrate pads (111 and 112) each have the same maximum width, the second substrate pads (121 and 122) each have the same maximum width, the first connecting pads (211 and 212) each have the same maximum width, and the first chip pads 315 each have the same maximum width, and curve (B) represents the loss of high-speed signals as a function of frequency when the maximum width of the (1-2)-th substrate pads 112 is less than the maximum width of the (1-1)-th substrate pads 111, and the maximum width of the (1-2)-th connecting pads 212 is less than the maximum width of the (1-1)-th connecting pads 211. As can be seen from FIG. 6, the loss of high-speed signals can be reduced by reducing the maximum widths of the (1-2)-th substrate pads 112 and the (1-2)-th connecting pads 212 that transmit high speed signals. Accordingly, high-speed signal with a wide range of frequencies can be used.

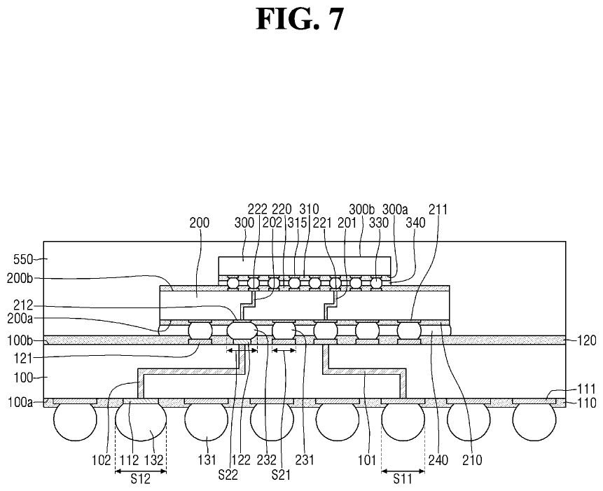

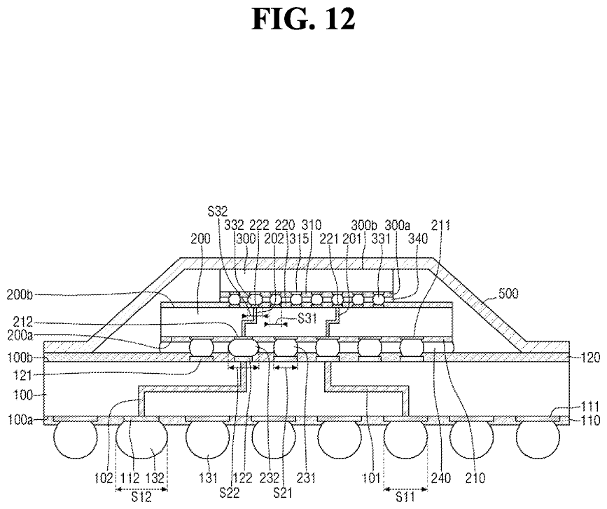

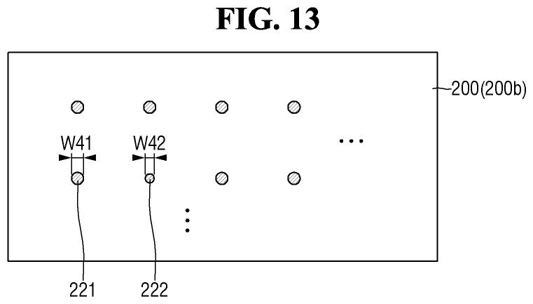

FIGS. 7 through 13 illustrate semiconductor packages according to some embodiments of the present disclosure. For example, FIG. 13 illustrates (2-1)-th connecting pads and (2-2)-th connecting pads of FIG. 12. For convenience of explanation, embodiments of FIGS. 7 through 13 will hereinafter be described by focusing mainly on differences with embodiment of FIGS. 1 through 6.

Referring to FIG. 7, in an embodiment, a semiconductor package includes a molding layer 550.

The molding layer 550 is disposed on a second surface 100b of a package substrate 100. The molding layer 550 is disposed on a second solder resist 120 and covers a first interposer 200 and a first semiconductor package 300. The molding layer 550 surrounds the sides of a first interposer 200 and the sides of a first semiconductor chip 300. For example, the molding layer 550 covers the top surface of the first semiconductor chip 300, but embodiments of the present disclosure are not necessarily limited thereto. For example, in an embodiment, the molding layer 550 exposes the top surface of the first semiconductor chip 300. For example, the top surface of the molding layer 550 is substantially coplanar with the top surface of the first semiconductor chip 300.

The molding layer 550 covers, for example, first and second underfill material layers 240 and 340, but embodiments of the present disclosure are not necessarily limited thereto. Alternatively, in an embodiment, the molding layer 550 surrounds second connecting terminals 231 and 232 and third connecting terminals 330, instead of the first and second underfill material layers 240 and 340, and fills the gaps between the second connecting terminals 231 and 232 and the gaps between the third connecting terminals 330.

The molding layer 550 includes, for example, an EMC or two or more types of silicon hybrid materials, but embodiments of the present disclosure are not necessarily limited thereto.

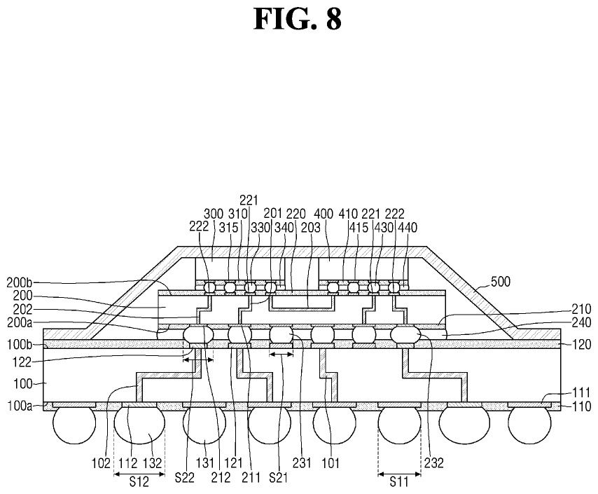

Referring to FIG. 8, in an embodiment, a semiconductor package further includes a second semiconductor chip 400.

The second semiconductor chip 400 is disposed on a first interposer 200. The second semiconductor chip 400 is disposed on a fourth surface 200b of the first interposer 200. The second semiconductor chip 400 is spaced apart from a first semiconductor chip 300 in a direction parallel to the fourth surface 200b of the first interposer 200. The second semiconductor chip 400 may be a semiconductor logic chip or a semiconductor memory chip.

Second chip pads 415 are disposed on the second semiconductor chip 400. The second chip pads 415 face the fourth surface 200b of the first interposer 200. The second chip pads 415 include a metal, such as Cu or Al, but embodiments of the present disclosure are not necessarily limited thereto. The number of second chip pads 415, and the distance between and the layout of the second chip pads 415 are not particularly limited.

A fourth passivation layer 410 is disposed on the second semiconductor chip 400. The fourth passivation layer 410 faces the fourth surface 200b of the first interposer 200. The fourth passivation layer 410 exposes at least parts of the second chip pads 415. The fourth passivation layer 410 includes silicon nitride. Alternatively, in an embodiment, the fourth passivation layer 410 includes a passivation material, such as at least one of BCB, polybenzoxazole, polyimide, epoxy, silicon oxide, silicon nitride, or a combination thereof.

Fourth connecting terminals 430 are disposed between the first interposer 200 and the second semiconductor chip 400. The fourth connecting terminals 430 are disposed between second connecting pads 221 and 222 and the second chip pads 415. The fourth connecting terminals 430 are disposed on and electrically connected to the second connecting pads 221 and 222 and the second chip pads 415. The fourth connecting terminals 320 are electrically connected to (2-1)-th connecting pads 221 to transmit ground signals, power signals, or first signals, or are electrically connected to (2-2)-th connecting pads 222 to transmit second signals. Accordingly, the second chip pads 415 transmit the ground signals, the power signals, or the first signals, or transmit the second signals.

In some embodiments, the second chip pads 415 each have substantially the same maximum width. The maximum width of the second chip pads 415 is the diameter of the second chip pads 415. For example, the second chip pads 415 that transmit the ground signals, the power signals, or the first signals, have substantially the same maximum width as that second chip pads 415 that transmit the second signals. The fourth connecting terminals 430 each have substantially the same maximum width. For example, the fourth connecting terminals 430 that transmit the ground signals, the power signals, or the first signals have substantially the same maximum width as the fourth connecting terminals 430 that transmit the second signals.

The fourth connecting terminals 430 may be, for example, solder bumps, but embodiments of the present disclosure are not necessarily limited thereto. The fourth connecting terminals 430 may have various shapes. such as a ball, pin, or pillar shape. The number of fourth connecting terminals 430, and the distance between and the layout of the fourth connecting terminals 430 are not particularly limited, and may vary. The fourth connecting terminals 430 have different sizes from the first and second connecting terminal 130 and 230. For example, first connecting terminals 130 are larger than second connecting terminals 230, and the second connecting terminals 230 are larger than the fourth connecting terminals 430.

The fourth connecting terminals 430 include, for example, at least one of Sn, In, Bi, Sb, Cu, Ag, Zn, Pb, or a combination thereof, but embodiments of the present disclosure are not necessarily limited thereto.

A third underfill material layer 440 is disposed between the first interposer 200 and the second semiconductor chip 400. The third underfill material layer 440 fills the gap between the first interposer 200 and the second semiconductor chip 400. The third underfill material layer 440 fills the gaps between the fourth connecting terminals 430 and surrounds the fourth connecting terminals 430. Alternatively, in an embodiment, the third underfill material layer 440 extends upwards along the sides of the fourth passivation layer 410 and the sides of the second semiconductor chip 400. The third underfill material layer 440 protects the fourth connecting terminals 430. The third underfill material layer 440 includes an insulating polymer material such as, for example, an EMC, but embodiments of the present disclosure are not necessarily limited thereto.

A heat dissipation structure 500 is disposed on a second surface 100b of a package substrate 100 and covers the first interposer 200, the first semiconductor chip 300, and the second semiconductor chip 400. The heat dissipation structure 500 is attached to, for example, the top surfaces of the first and second semiconductor chips 300 and 400.

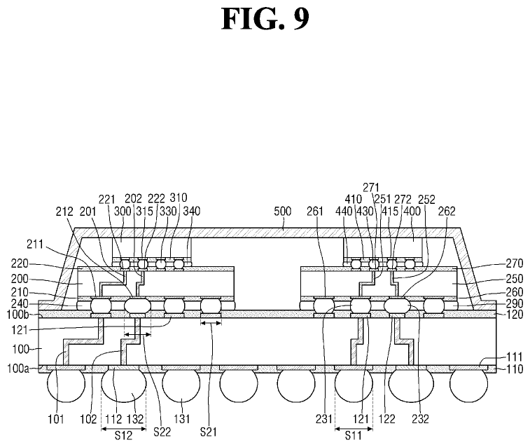

Referring to FIG. 9, in an embodiment, a semiconductor package further includes a second interposer 250 and a second semiconductor chip 400.

The second interposer 250 is disposed on a second surface 100b of a package substrate 100 and is spaced apart from a first interposer 200. The second interposer 250 may be, for example, a silicon interposer. Alternatively, in an embodiment, the second interposer 250 includes at least one of, for example, glass, ceramic, or plastic.

Third connecting pads 261 and 262 and a fifth passivation layer 260 are disposed on the bottom surface of the second interposer 250, and the bottom surface of the second interposer 250 faces the second surface 100b of the package substrate 100. The fifth passivation layer 260 exposes at least parts of the third connecting pads 261 and 262.

Fourth connecting pads 271 and 272 and a sixth passivation layer 270 are disposed on the top surface of the second interposer 250. The sixth passivation layer 270 exposes at least parts of the fourth connecting pads 271 and 272. The third connecting pads 261 and 262 and the fourth connecting pads 271 and 272 include a metal, such as Cu or Al, but embodiments of the present disclosure are not necessarily limited thereto.

Third wiring patterns 251 and 252 are disposed in the second interposer 250. (3-1)-th wiring patterns 251 and (3-2)-th wiring patterns 252 are similar to the (2-1)-th wiring patterns 201 and the (2-2)-th wiring patterns 202, respectively, and thus, detailed descriptions thereof will be omitted.

Second connecting terminals 231 and 232 are disposed between second substrate pads 121 and 122 and the third connecting pads 261 and 262. (2-1)-th connecting terminals 231 are electrically connected to (2-1)-th substrate pads 121 and (3-1)-th connecting pads 261, and (2-2)-th connecting terminals 232 are electrically connected to (2-2)-th substrate pads 122 and (3-2)-th connecting pads 262. The (3-1)-th connecting pads 261 are electrically connected to the (3-1)-th wiring patterns 251 and (4-1)-th connecting pads 271, and the (3-2)-th connecting pads 262 are electrically connected to the (3-2)-th wiring patterns 252 and (4-2)-th connecting pads 272.

In some embodiments, the maximum width of the (3-1)-th connecting pads 261 differs from the maximum width of the (3-2)-th connecting pads 262. The maximum width of the (3-2)-th connecting pads 262 that transmit second signals is less than the maximum width of the (3-1)-th connecting pads 261 that do not transmit the second signals. For example, the maximum width of the (3-1)-th connecting pads 261 is the diameter of the (3-1)-th connecting pads 261, and the maximum width of the (3-2)-th connecting pads 262 is the diameter of the (3-2)-th connecting pads 262.

In some embodiments, the maximum width of (4-1)-th connecting pads 271 that do not transmit the second signals are substantially the same as the maximum width of (4-2)-th connecting pads 272 that transmit the second signals. For example, the maximum width of the (4-1)-th connecting pads 271 is the diameter of the (4-1)-th connecting pads 271, and the maximum width of the (4-2)-th connecting pads 272 is the diameter of the (4-2)-th connecting pads 272.

The second semiconductor chip 400 is disposed on the second interposer 250. The fourth connecting terminals 430 are electrically connected to the fourth connecting pads 271 and 272 and second chip pads 415. The second semiconductor chip 400, a fourth passivation layer 410, the second chip pads 415, and a third underfill material layer 440 are similar to their respective counterparts of FIG. 8, and thus, detailed descriptions thereof will be omitted.

In some embodiments, a heat dissipation structure 500 is disposed on the second surface 100b of the package substrate 100 and covers the first interposer 200, the second interposer 250, the first semiconductor chip 300, and the second semiconductor chip 400.

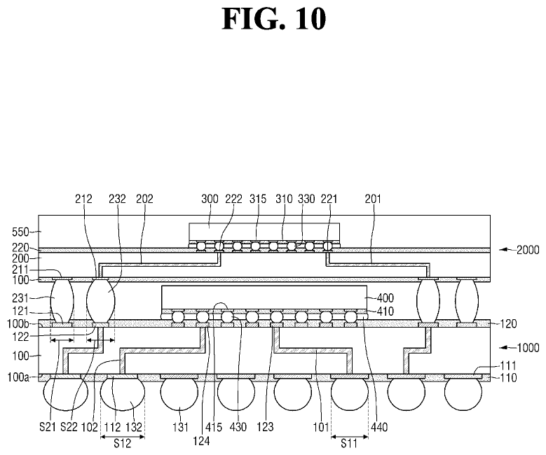

Referring to FIG. 10, in an embodiment, a semiconductor package includes first and second packages 1000 and 2000.

The first package 1000 includes a package substrate 100 and a second semiconductor chip 400. (2-3)-th substrate pads 123 and (2-4)-th substrate pads 124 are disposed on a second surface 200a of the package substrate 100. Second solder resist 120 exposes at least parts of the (2-3)-th substrate pads 123 and at least parts of the (2-4)-th substrate pads 124. The (2-3)-th substrate pads 123 are electrically connected to (1-1)-th wiring patterns 101, and the (2-4)-th substrate pads 124 are electrically connected to (1-2)-th wiring patterns 102. Fourth connecting terminals 430 are electrically connected to the (2-3)-th substrate pads 123, the (2-4)-th substrate pads 124, and second chip pads 415. A second semiconductor chip 400, a fourth passivation layer 410, the second chip pads 415, and a third underfill material layer 440 are similar to their respective counterparts of FIG. 8, and thus, detailed descriptions thereof will be omitted.

In some embodiments, the maximum width of the (2-4)-th substrate pads 124, which transmit second signals, are substantially the same as the maximum width of the (2-3)-th substrate pads 123, which do not transmit the second signals. Alternatively, in some embodiments, the maximum width of the (2-4)-th substrate pads 124, which transmit the second signals, is greater than the maximum width of the (2-3)-th substrate pads 123, which do not transmit the second signals.

The second package 2000 includes an interposer 200 and a first semiconductor chip 300. The first and second packages 1000 and 2000 are electrically connected by second connecting terminals 231 and 232.

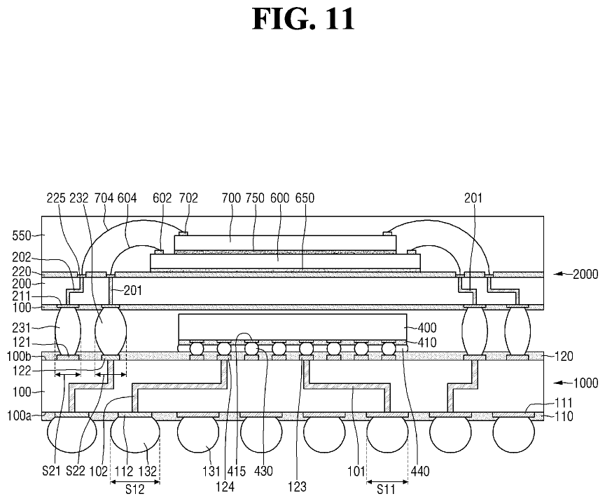

Referring to FIG. 11, in an embodiment, a semiconductor package includes first and second packages 1000 and 2000. The first package 1000 is similar to its counterpart of FIG. 10, and thus, a detailed description thereof will be omitted.

The second package 2000 includes an interposer 200 and third and fourth semiconductor chips 600 and 700 disposed on the interposer 200. The fourth semiconductor chip 700 is stacked on the third semiconductor chip 600. The number of semiconductor chips disposed on the interposer 200, i.e., the number of third semiconductor chips 600 and fourth semiconductor chips 700, is not particularly limited. Alternatively, in an embodiment, a semiconductor chip is further disposed on the interposer 200 and spaced apart from the third and fourth semiconductor chips 600 and 700 in a direction parallel to a top surface of the interposer 200.

The third semiconductor chip 600 is attached to the top surface of the interposer 200 by a first adhesive layer 650. The fourth semiconductor chip 700 is attached to the top surface of the third semiconductor chip 600 by a second adhesive layer 750. Each of the first and second adhesive layers 650 and 750 include at least one of, for example, a liquid epoxy, an adhesive tape, a conductive medium, or a combination thereof, but embodiments of the present disclosure are not necessarily limited thereto.

The third semiconductor chip 600 is electrically connected to the interposer 200 by first bonding wires 604. The fourth semiconductor chip 700 is electrically connected to the interposer 200 by second bonding wires 704. For example, the first bonding wires 604 electrically connect third chip pads 602 of the third semiconductor chip 600 and fifth connecting pads 225 of the interposer 200. For example, the second bonding wires 704 electrically connect fourth chip pads 702 of the fourth semiconductor chip 700 and the fifth connecting pads 225 of the interposer 200.

Referring to FIGS. 12 and 13, in an embodiment, a maximum width W42 of (2-2)-th connecting pads 222, which are electrically connected to (2-2)-th wiring patterns 202 and transmit second signals, is less than a maximum width W41 of (2-1)-th connecting pads 221, which are electrically connected to (2-1)-th wiring patterns 201 and do not transmit the second signals.

(3-1)-th connecting terminals 331 are electrically connected to the (2-1)-th connecting pads 221 and first chip pads 315. (3-2)-th connecting terminals 332 are electrically connected to the (2-2)-th connecting pads 222 and the first chip pads 315. In some embodiments, a maximum width S31 of the (3-1)-th connecting terminals 331 differs from a maximum width S32 of the (3-2)-th connecting terminals 332. The maximum width S32 of the (3-2)-th connecting terminals 332, which transmit the second signals, is less than the maximum width S31 of the (3-1)-th connecting terminals 331, which do not transmit the second signals.

Embodiments of the present disclosure have been described above with reference to the accompanying drawings, but embodiments of the present disclosure are not necessarily limited thereto and may be implemented in various different forms. It will be understood that embodiments of the present disclosure can be implemented in other specific forms without changing the technical spirit or gist of embodiments of the present disclosure. Therefore, it should be understood that embodiments set forth herein are illustrative in all respects and not limiting.

What is claimed is:

1. A semiconductor package, comprising:
a package substrate that includes first and second surfaces that are opposite to each other;
(1-1)-th substrate pads and (1-2)-th substrate pads disposed on the first surface of the package substrate, wherein the (1-2)-th substrate pads have a smaller maximum width than the (1-1)-th substrate pads;
first connecting terminals disposed on the (1-1)-th substrate pads and the (1-2)-th substrate pads;
(2-1)-th substrate pads and (2-2)-th substrate pads disposed on the second surface of the package substrate, wherein the (2-2)-th substrate pads have a smaller maximum width than the (2-1)-th substrate pads;
an interposer disposed on the second surface of the package substrate;
second connecting terminals disposed between the (2-1)-th substrate pads, the (2-2)-th substrate pads, and the interposer; and
a first semiconductor chip disposed on the interposer,
wherein
the (1-1)-th substrate pads and the (2-1)-th substrate pads transmit first signals, ground signals, or power signals, and
the (1-2)-th substrate pads and the (2-2)-th substrate pads transmit second signals that are faster than the first signals.

2. The semiconductor package of claim 1, wherein
the first connecting terminals include (1-1)-th connecting terminals disposed on the (1-1)-th substrate pads and (1-2)-th connecting terminals disposed on the (1-2)-th substrate pads, and
a maximum width of the (1-2)-th connecting terminals is greater than a maximum width of the (1-1)-th connecting terminals.

3. The semiconductor package of claim 2, wherein bottom surfaces of the (1-2)-th connecting terminals are coplanar with bottom surfaces of the (1-1)-th connecting terminals.

4. The semiconductor package of claim 1, further comprising:
(1-1)-th connecting pads and (1-2)-th connecting pads disposed on a third surface of the interposer that faces the second surface of the package substrate, wherein the (1-2)-th connecting pads have a smaller maximum width than the (1-1)-th connecting pads,
wherein the second connecting terminals include (2-1)-th connecting terminals that are disposed between the (1-1)-th connecting pads and the (2-1)-th substrate pads, and (2-2)-th connecting terminals that are disposed between the (1-2)-th connecting pads and the (2-2)-th substrate pads.

5. The semiconductor package of claim 4, wherein a maximum width of the (2-2)-th connecting terminals is greater than a maximum width of the (2-1)-th connecting terminals.

6. The semiconductor package of claim 1, further comprising:
(2-1)-th connecting pads and (2-2)-th connecting pads disposed on a fourth surface of the interposer that faces the first semiconductor chip, wherein the (2-1)-th connecting pads and the (2-2)-th connecting pads have a same maximum width,
wherein
the (2-1)-th connecting pads transmit the first signals, the ground signals, or the power signals, and
the (2-2)-th connecting pads transmit the second signals.

7. The semiconductor package of claim 1, further comprising:
(2-1)-th connecting pads and (2-2)-th connecting pads disposed on a fourth surface of the interposer that faces the first semiconductor chip, wherein the (2-2)-th connecting pads have a smaller maximum width than the (2-1)-th connecting pads,
wherein
the (2-1)-th connecting pads transmit the first signals, the ground signals, or the power signals, and
the (2-2)-th connecting pads transmit the second signals.

8. The semiconductor package of claim 1, further comprising:
a heat dissipation structure disposed on the second surface of the package substrate, wherein the heat dissipation structure covers the first semiconductor chip.

9. The semiconductor package of claim 1, further comprising:
a molding layer disposed on the second surface of the package substrate, wherein the molding layer covers the interposer and the first semiconductor chip.

10. The semiconductor package of claim 1, further comprising:
a molding layer disposed on the second surface of the package substrate, wherein the molding layer surrounds the interposer and the first semiconductor chip and exposes a top surface of the first semiconductor chip.

11. The semiconductor package of claim 1, further comprising:
a second semiconductor chip disposed on the interposer, wherein the second semiconductor chip is spaced apart from the first semiconductor chip.

12. The semiconductor package of claim 1, further comprising:
a second semiconductor chip disposed on the second surface of the package substrate.

13. The semiconductor package of claim 12, further comprising:
third connecting terminals disposed between the first semiconductor chip and the interposer;
(2-3)-th substrate pads and (2-4)-th substrate pads disposed on the second surface of the package substrate, wherein the (2-3)-th substrate pads and (2-4)-th substrate pads have a same maximum width; and
fourth connecting terminals disposed between the (2-3)-th substrate pads, the (2-4)-th substrate pads, and the second semiconductor chip,
wherein
the (2-3)-th substrate pads transmit the first signals, the ground signals, or the power signals, and
the (2-4)-th substrate pads transmit the second signals.

14. A semiconductor package, comprising:
a package substrate that includes first and second surfaces that are opposite to each other;
first connecting terminals disposed on the first surface of the package substrate;
an interposer disposed on the second surface of the package substrate, wherein the interposer includes a third surface that faces the second surface and a fourth surface that is opposite to the third surface;
(1-1)-th connecting pads and (1-2)-th connecting pads disposed on the third surface of the interposer, wherein the (1-2)-th connecting pads have a smaller maximum width than the (1-1)-th connecting pads;
second connecting terminals disposed between the (1-1)-th connecting pads, the (1-2)-th connecting pads, and the package substrate;
(2-1)-th connecting pads and (2-2)-th connecting pads disposed on the fourth surface of the interposer, wherein the (2-1)-th connecting pads and the (2-2)-th connecting pads have a same maximum width;
a semiconductor chip disposed on the fourth surface of the interposer; and
third connecting terminals disposed between the (2-1)-th connecting pads, the (2-2)-th connecting pads, and the semiconductor chip,
wherein
the (1-1)-th connecting pads and the (2-1)-th connecting pads transmit first signals, ground signals, or power signals, and
the (1-2)-th connecting pads and the (2-2)-th connecting pads transmit second signals, which are faster than the first signals.

15. The semiconductor package of claim 14, wherein
the second connecting terminals include (2-1)-th connecting terminals disposed on the (1-1)-th connecting pads and (2-2)-th connecting terminals disposed on the (1-2)-th connecting pads, and
a maximum width of the (2-2)-th connecting terminals is greater than a maximum width of the (2-1)-th connecting terminals.

16. The semiconductor package of claim 14, further comprising:
first chip pads and second chip pads disposed on the semiconductor chip, wherein the first chip pads and the second chip pads have a same width,
wherein the third connecting terminals are disposed on the first chip pads and the second chip pads,
the first chip pads transmit the first signals, the ground signals, or the power signals, and
the second chip pads transmit the second signals.

17. The semiconductor package of claim 14, further comprising:
(1-1)-th substrate pads and (1-2)-th substrate pads disposed on the first surface of the package substrate, wherein the (1-1)-th substrate pads and the (1-2)-th substrate pads have the first connecting terminals disposed thereon,
wherein
a maximum width of the (1-2)-th substrate pads is less than a maximum width of the (1-1)-th substrate pads,
the (1-1)-th substrate pads transmit the first signals, the ground signals, or the power signals, and
the (1-2)-th substrate pads transmit the second signals.

18. The semiconductor package of claim 14, further comprising:
a first underfill material layer disposed on the second surface of the package substrate, wherein the first underfill material layer surrounds the second connecting terminals;
a second underfill material layer disposed on the fourth surface of the interposer, wherein the second underfill material layer surrounds the third connecting terminals; and
a heat dissipation structure disposed on the second surface of the package substrate, wherein the heat dissipation structure covers the semiconductor chip.

19. The semiconductor package of claim 14, further comprising:
a molding layer disposed on the second surface of the package substrate, wherein the molding layer covers the semiconductor chip and the interposer.

20. A semiconductor package, comprising:
a package substrate that includes first and second surfaces that are opposite to each other;
(1-1)-th substrate pads and (1-2)-th substrate pads disposed on the first surface of the package substrate, wherein the (1-2)-th substrate pads have a smaller maximum width than the (1-1)-th substrate pads;
first connecting terminals disposed on the (1-1)-th substrate pads and the (1-2)-th substrate pads;
(2-1)-th substrate pads and (2-2)-th substrate pads disposed on the second surface of the package substrate, wherein the (2-2)-th substrate pads have a smaller maximum width than the (2-1)-th substrate pads;
an interposer disposed on the second surface of the package substrate, wherein the interposer includes a third surface that faces the second surface and a fourth surface that is opposite to the third surface;
(1-1)-th connecting pads and (1-2)-th connecting pads disposed on the third surface of the interposer, wherein the (1-2)-th connecting pads have a smaller maximum width than the (1-1)-th connecting pads;
second connecting terminals disposed between the (2-1)-th substrate pads and the (1-1)-th connecting pads and between the (2-2)-th substrate pads and the (1-2)-th connecting pads;
(2-1)-th connecting pads and (2-2)-th connecting pads disposed on the fourth surface of the interposer, wherein the (2-1)-th connecting pads and the (2-2)-th connecting pads have a same maximum width;
a semiconductor chip disposed on the fourth surface of the interposer;
first chip pads and second chip pads disposed on a fifth surface of the semiconductor chip that faces the fourth surface of the interposer, wherein the first chip pads and the second chip pads have a same width; and
third connecting terminals disposed between the (2-1)-th connecting pads and the first chip pads and between the (2-2)-th connecting pads and the second chip pads,
wherein
the (1-1)-th substrate pads, the (2-1)-th substrate pads, the (1-1)-th connecting pads, the (2-1)-th connecting pads, and the first chip pads transmit first signals, ground signals, or power signals, and
the (1-2)-th substrate pads, the (2-2)-th substrate pads, the (1-2)-th connecting pads, the (2-2)-th connecting pads, and the second chip pads transmit second signals that have a different speed from the first signals.
